(19) United States
(12) Patent Application Publication
(10) Pub. No.: US 2025/0014893 A1
(43) Pub. Date: Jan. 9, 2025

(54) ATOMIC LAYER DEPOSITION SEAM REDUCTION

(71) Applicant: Lam Research Corporation, Fremont, CA (US)

(72) Inventors: Douglas Walter Agnew, Portland, OR (US); Jonathan Grant Baker, King City, OR (US)

(21) Appl. No.: 18/705,428

(22) PCT Filed: Oct. 27, 2022
(86) PCT No.: PCT/US2022/048098

§ 371 Date: Apr. 26, 2024

Related U.S. Application Data
(60) Provisional application No. 63/263,323, filed on Oct. 29, 2021.

(51) Int. Cl. H01L 21/02; C23C 14/08; C23C 14/34; C23C 16/40; C23C 16/44; C23C 16/455; C23C 28/00; C23C 28/04

(52) U.S. Cl. CPC H01L 21/02266; C23C 14/08; C23C 14/34; C23C 16/40; C23C 16/4408; C23C 16/45536; C23C 28/04; C23C 28/40; H01L 21/02274; H01L 21/0228

(57) ABSTRACT

Methods and apparatuses for depositing material into features are described herein. Methods involve depositing an oxide material and then sputtering the oxide material to reduce seams. The oxide material may be deposited by an ALD process.

### INCORPORATED BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Many semiconductor device fabrication processes involve forming films including oxide films such as silicon oxide. Deposition of silicon oxide films may involve chemical vapor deposition (CVD) or atomic layer deposition (ALD), as well as plasma enhanced depositions, but in some cases it may be difficult to achieve a high quality film. This can be a particular challenge when depositing films in gaps.

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Presented herein are various methods and systems for depositing oxide material into features of a substrate. In one aspect of the embodiments herein, a method of depositing an oxide material is presented, the method including: receiving a semiconductor substrate in a process chamber; depositing a conformal seed layer of oxide material into patterned features of a layer of the semiconductor substrate; and one or more cycles including: sputtering the oxide material using an inert gas in the presence of a plasma generated by a dual radio frequency (RF) plasma source including a high frequency (HF) component and a low frequency (LF) component; and depositing oxide material into the patterned features by an atomic layer deposition (ALD) process. In some embodiments, each cycle of the one or more cycles includes: sputtering the oxide material and conformally depositing oxide material by multiple cycles of the ALD process. In some embodiments, each cycle of the one or more cycles further includes: flowing oxide precursor into the process chamber; flowing purge gas into the process chamber; flowing an oxygen-containing species and an inert gas into the process chamber; and flowing purge gas into the process chamber. In some embodiments, the oxide precursor is an amino group containing siloxane. In some embodiments, the oxide precursor is a disiloxane having the formula X(R¹)ₐSi—O—Si(R²)_{b}Y, wherein a and b are integers from 0 to 2, wherein X and Y independently can be H or NR³R⁴, and wherein each of R¹, R², R³ and R⁴ is hydrogen, unbranched alkyl, branched alkyl, saturated heterocyclic, unsaturated heterocyclic groups, or combinations thereof. In some embodiments, X, Y, or both are NR³R⁴, and R³, R⁴, and the atom to which they are attached form a saturated heterocyclic compound. In some embodiments, the plasma source has a non-zero LF component power during flowing the oxygen-containing species and inert gas. In some embodiments, the volumetric flow ratio between the inert gas and the oxygen-containing species is at least about 1:1. In some embodiments, the volumetric flow ratio between the inert gas and the oxygen-containing species is between about 1:1 and 6:1.

In some embodiments, the method further includes a first cycle of the one or more cycles and a second cycle of the one or more cycles, wherein the LF component power, process chamber pressure, ratio between the inert gas and oxygen-containing species, or any combination thereof is different between the second cycle and the first cycle. In some embodiments, the process chamber pressure is lower during the second cycle than during the first cycle. In some embodiments, a ratio between the inert gas and the oxygen-containing species is higher during the second cycle than during the first cycle. In some embodiments, the LF component power is higher during the second cycle than during the first cycle.

In some embodiments, the oxide material is at least about 6.5 nm thick prior to sputtering. In some embodiments, further including flowing oxygen-containing species into the process chamber during sputtering. In some embodiments, the one or more cycles include at least about 100 cycles. In some embodiments, the LF component power during sputtering is at least about 500 W. In some embodiments, the LF component power during sputtering is between about 500 W and 5 kW. In some embodiments, the HF component power is between about 500 W and about 6.5 kW. In some embodiments, the pressure of the process chamber is between about 10 mTorr and about 20 Torr. In some embodiments, the ALD process is performed in the presence of a plasma. In some embodiments, the LF component power during the ALD process is OW and the LF component power is at least about 1000 kW during sputtering. In some embodiments, the inert gas includes argon. In some embodiments, the oxide material does not have a seam at least about 50 nm below the top of the patterned features. In some embodiments, the patterned feature have an aspect ratio of between about 1:1 and about 10:1.

In another aspect of the embodiments herein, another method of depositing an oxide material is disclosed, the method including: receiving a semiconductor substrate in a process chamber; depositing a conformal seed layer of oxide material into patterned features of a layer of the semiconductor substrate; depositing oxide material by a plasma enhanced atomic layer deposition (PEALD) process, wherein the process includes: igniting a plasma generated by a dual radio frequency (RF) plasma source including a high frequency (HF) component and a low frequency (LF) component, flowing oxide precursor into the process chamber, flowing purge gas into the process chamber, flowing an oxygen-containing species and an inert gas into the process chamber, flowing purge gas into the process chamber, and wherein the LF component power is increased during flowing an oxygen-containing species and an inert gas.

These and other features of the disclosed embodiments will be described in detail below with reference to the associated drawings.

### BRIEF DESCRIPTION OF DRAWINGS

FIG. 1A presents an illustration of a seam in a feature.

FIG. 1B presents illustrations of a process to deposit oxide material using a sputtering operation according to an example embodiment.

FIG. 2 presents a flow diagram of operations for one example embodiment.

FIG. 3 presents a flow diagram for an atomic layer deposition (ALD) cycle.

FIG. 4 presents illustrations of a process to deposit oxide material using multiple sputtering operations according to embodiments herein.

FIG. 5 presents a flow diagram of operations for another example embodiment.

FIGS. 6-9 are schematic diagrams of examples of process chambers for performing methods in accordance with disclosed embodiments.

### DETAILED DESCRIPTION

This disclosure describes techniques for depositing oxide into features of a layer on a semiconductor substrate. Semiconductor fabrication processes often include dielectric gap fill using chemical vapor deposition (CVD) and/or atomic layer deposition (ALD) methods to fill features. Described herein are methods of filling features with dielectric material including but not limited to silicon oxide, and related systems and apparatuses. The methods described herein can be used to fill vertically-oriented features formed in a substrate. Such features may be referred to as gaps, recessed features, negative features, unfilled features, or simply features. Filling such features may be referred to as gapfill. Features formed in a substrate can be characterized by one or more of narrow and/or re-entrant openings, constrictions within the feature, and high aspect ratios. In some implementations, a feature may have an aspect ratio of at least about 2:1, at least about 4:1, at least about 6:1, at least about 10:1, at least about 30:1, at least about 50:1, or greater. In some embodiments techniques herein may be used to fill trenches with minimal/reduced voids. In other embodiments techniques herein may be used to fill features where a portion of the deposited material has reduced voids/is seam-free until a certain depth from the top of the feature, and below that depth a seam may form without significantly impacting performance of the deposited material. The substrate may be a silicon wafer, e.g., a 200-mm wafer, a 300-mm wafer, or a 450-mm wafer, including wafers having one or more layers of material such as dielectric, conducting, or semi-conducting material deposited thereon.

A gapfill deposition process for oxide films may create seams in the deposited film. As the film conformally grows within a feature, a seam may form at the juncture between the films as they grow towards each from the sidewalls of the feature. Seams may be less dense areas of the oxide film and contribute to worse film qualities. Seams are generally undesirable due to increasing the chance of failure of a resulting semiconductor device.

Described herein are techniques to address seams that may otherwise form during deposition of an oxide gapfill material. In particular, sputtering of the oxide material during deposition may reduce seam formation. Oxide gapfill material, oxide film, and oxide material may be used interchangeably herein.

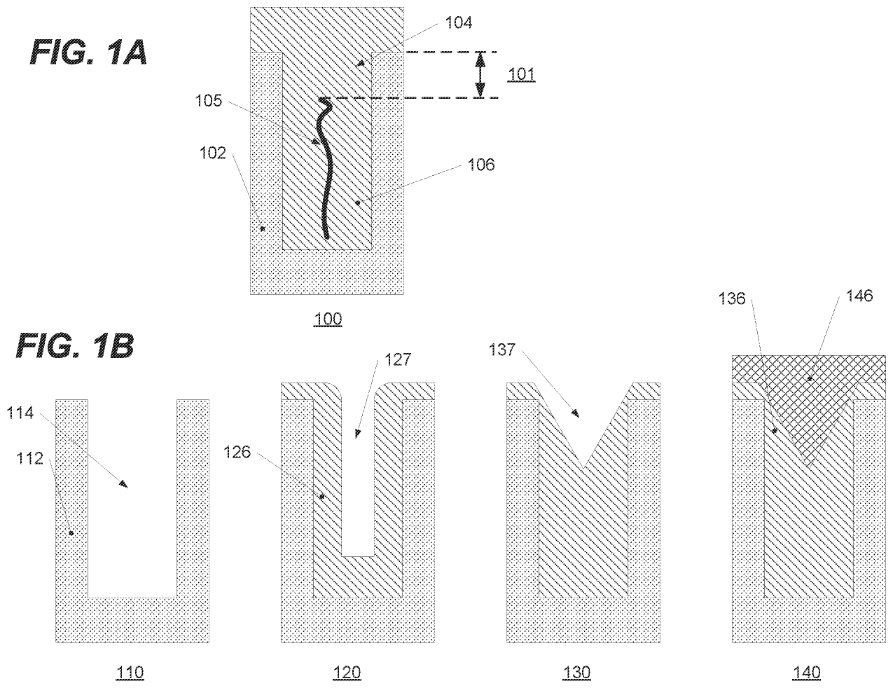

FIG. 1A provides an illustration of a seam in a filled feature. In diagram 100, a substrate is presented having a patterned layer 102, a feature 104 within the patterned layer 102, and an oxide material 106 deposited within the feature 104. The oxide material has a seam 105. In the embodiment of FIG. 1A, seam 105 may also be characterized by a depth 101 between the seam 105 and the top of the patterned layer 102 and/or top of the feature 104.

In some embodiments, techniques described herein may fill features without forming seams. In other embodiments, a seam may form but to a reduced extent. In such embodiments, the seam may be characterized by a depth (as described in FIG. 1A) of at least about 40 nm, at least about 50 nm, or at least about 60 nm.

FIG. 1B provides illustrations of a process to reduce seams. In diagram 110, a substrate having a patterned layer 112 and a feature 114 is presented. In diagram 120, oxide material 126 is deposited on the patterned layer 112 and within the feature 114. As the oxide material has not completely filled the feature, a gap 127 is present within the feature 114 and defined by the oxide material. It should be understood that while oxide material 126 is shown as depositing above patterned layer 112, in some embodiments there is no deposition on top of patterned layer 112, and oxide material 126 is only deposited within feature 114.

In diagram 130, the oxide material 126 has been sputtered. Sputtering may include etching and re-depositing of material, such as the oxide material. In some embodiments some of the material that is etched then re-deposits back onto the substrate. The result of sputtering may include oxide material near the top of the feature re-depositing at the bottom of the feature, facilitating a bottom-up fill mechanism that reduces the formation of seams.

Another result of sputtering is a tapering of the gap from the top of the feature 114. As shown in diagram 130, the gap 127, which may be somewhat rectangular in shape, has become a gap 137 having a more triangular shape that is wider at the top of the feature and tapers towards the bottom of the feature. As noted above, conformal film deposition may result in a seam as the films grow towards each other from the sidewalls of the feature. For example, the gap 127 may continue to shrink until reactants fail to adsorb and/or react in the gap, resulting in a less dense region described as a seam. In the example of FIG. 1B, sputtering the oxide material changes the shape of the gap and re-deposits oxide material at the bottom of the feature. This reduces the risk that later deposition processes to deposit oxide material in the gap 137 produce seams. It also reduces the risk that later deposition processes result in a void in the oxide material.

In diagram 140, additional oxide material 146 is deposited into the feature. Oxide material 126 and 146 may be the same or different oxide material (i.e. the shading in FIG. 1B is for purposes of illustration and should not be construed as requiring a difference between the chemical composition of oxide material 136 and 146). In some embodiments oxide material 146 may be deposited by a similar process as oxide material 126, while in other embodiments a different process may be performed. In some embodiments oxide material 126 and 146 do not include a seam, at least in part due to sputtering of the oxide material. While a seam is not shown in diagram 140, it should be understood that in some embodiments a seam is formed, but is present to a lesser degree compared to not having performed a sputter process. In some embodiments a seam may be present but the depth of the seam (as discussed above in reference to FIG. 1A) may be larger, i.e. the seam is smaller, compared to a seam that may form without performing a sputter process.

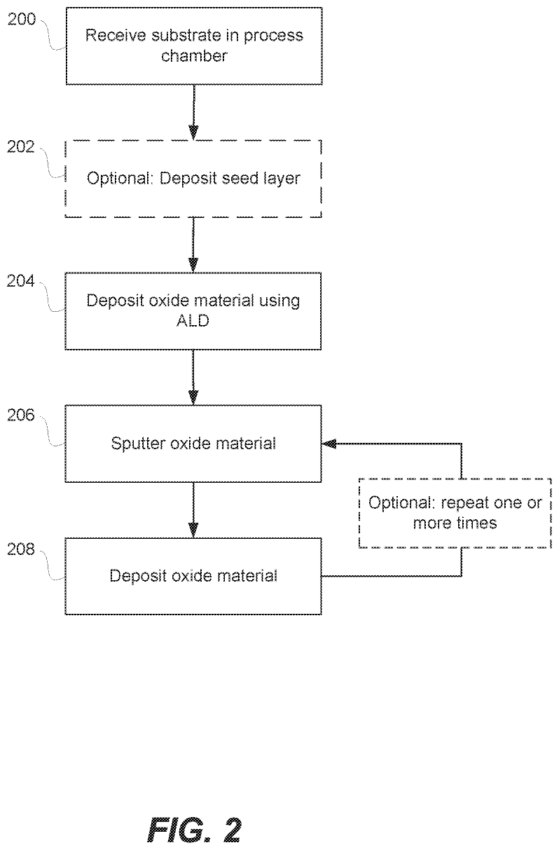

FIG. 2 presents a process flow diagram for embodiments described herein. In operation 200, a substrate having features to be filled is received in a process chamber. In some embodiments, the substrate may be remaining in the process chamber from a prior operation, while in other embodiments the substrate may be provided to the process chamber. The substrate has patterned features to be filled. In some embodiments, patterned features may have an aspect ratio between width and depth of between about 5:1 and about 10:1.

In operation 202 a seed layer may be optionally deposited within the feature. A seed layer may help facilitate later deposition operations and/or protect the underlying layer. For example, where oxide material is deposited by a plasma-enhanced process, the seed layer may protect an underlying layer from etching by ions produced by the plasma. In some embodiments the seed layer may be an oxide material that is the same as or different than the oxide material deposited in later operations as described herein. In various embodiments the seed layer may include any oxide material described herein or other suitable materials to facilitate deposition of oxide material. In some embodiments, the seed layer may be doped or undoped silicon nitride. In various embodiments the seed layer may be deposited by ALD, plasma-enhanced ALD (PEALD), CVD, or plasma-enhanced CVD (PECVD). ALD is a technique that deposits thin layers of material using sequential self-limiting reactions. ALD processes use surface-mediated deposition reactions to deposit films on a layer-by-layer basis in cycles. As an example, an ALD cycle may include the following operations: (i) delivery/adsorption of a precursor, (ii) purging of the precursor from the chamber, (iii) delivery of a second reactant and optional plasma ignition, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc.

In one example of an ALD process, a substrate surface that includes a population of surface active sites is exposed to a gas phase distribution of a first precursor, such as a silicon-containing precursor, in a dose provided to a chamber housing the substrate. Molecules of this first precursor are adsorbed onto the substrate surface, including chemisorbed species and/or physisorbed molecules of the first precursor. It should be understood that when a compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an oxygen-containing gas, is introduced to the chamber so that some of these molecules react with the first precursor adsorbed on the surface. In some processes, the second reactant reacts immediately with the adsorbed first precursor. In other embodiments, the second reactant reacts only after a source of activation such as plasma is applied temporally. The chamber may then be evacuated again to remove unbound second reactant molecules. As described above, in some embodiments the chamber may not be completely evacuated. Additional ALD cycles may be used to build film thickness.

In some implementations, the ALD methods include plasma activation. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” which is herein incorporated by reference in its entirety.

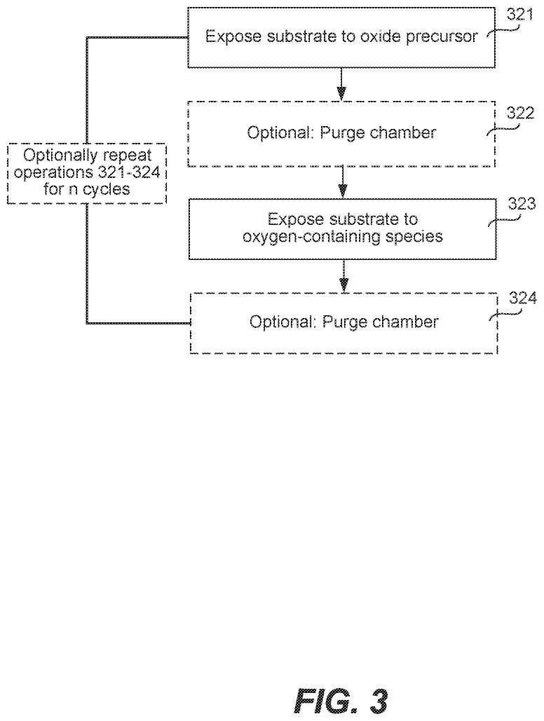

FIG. 3 presents a process flow diagram for a single ALD cycle. In operations 321, the substrate is exposed to a silicon-containing precursor, such as any of those described herein, to adsorb the precursor onto the surface of the feature. In various embodiments, this operation is self-limiting. In some embodiments, the precursor adsorbs to less than all of the active sites on the surface of the feature. In operation 322, the process chamber is optionally purged to remove any unadsorbed silicon-containing precursors. In operation 323, the substrate is exposed to an oxidizing chemistry and a plasma is ignited to form a first silicon oxide layer in the feature. In various embodiments, operation 323 converts the adsorbed silicon-containing precursor layer to silicon oxide. In operation 324, the process chamber is optionally purged to remove byproducts from the reaction between the silicon-containing precursor and the oxidant. Operations 321 through 324 may be optionally repeated for two or more cycles as desired to deposit silicon oxide to a desired thickness in the feature.

It should be noted that the processes described herein are not limited to a particular reaction mechanism. Thus, the process described with respect to FIG. 3 include all oxide deposition processes that use sequential exposures to a silicon-containing reactants and oxidizing plasmas, including those that are not strictly self-limiting. The process includes sequences in which one or more gases used to generate a plasma is continuously flowed throughout the process with intermittent plasma ignitions. Further, in some embodiments, thermal (non-plasma) ALD using the described chemistries may be employed.

Returning to FIG. 2, in operation 204 the patterned features are filled with an oxide material. In various embodiments, the oxide material is silicon oxide. In some embodiments, the oxide material may be a metal oxide, e.g., GeO₂, HfO₂, AlO₃, etc., or any combinations thereof. In some embodiments the oxide material is deposited by an ALD process or a PEALD process. In some embodiments, operation 204 deposits an oxide film having a thickness of at least about 6.5 nm, or between about 5% and about 35% of the feature to be filled's critical dimension or width.

In operation 206 the oxide material is sputtered. Sputtering may be performed in the presence of a plasma. In some embodiments sputtering involves igniting a plasma using a dual RF plasma source to produce a plasma having a low frequency (LF) component and a high frequency (HF) component. Without being bound by theory, the HF component functions to maintain the plasma, while the LF component may generate ions of an inert gas that bombard the substrate. In some embodiments the inert gas may comprise helium, nitrogen, argon, or xenon. By bombarding the oxide material with ions, the oxide material may be sputtered, re-depositing at least some of the oxide material deeper into features of the substrate, as illustrated in FIG. 1B.

While sputtering has been used in high density plasma (HDP) processes, the process conditions for HDP processes are significantly different. HDP processes may use an inductively-coupled plasma having a much higher ion bombardment and resulting in a different film compared to a capacitively-coupled PEALD process using a dual RF source as described herein. For example, HDP reactors may operate at less than 100 m Torr with a plasma density greater than 1011 ions/cm3, while PEALD or PECVD processes described herein may operate at a pressure greater than about 500 mTorr with a plasma density about 100× lower. Furthermore, in an HDP reactor, 400 KHz (i.e. LF component) may be used to generate a plasma (i.e., applied to the coils) and 13.56 MHz (i.e. HF component) is applied to a pedestal on which a wafer may be located during operation. However, in a capacitively-coupled plasma process as described herein, 13.56 MHz may also be used to generate the plasma and 400 KHz may control the ion bombardment of the wafer. In a capacitively-coupled plasma the ion energy cannot be modulated by 13.56 MHz as the reactor is operating at a higher pressure with higher ion-neutral collision frequencies. The LF component may be used to control ion energies impacting the wafer, and the ion energies are much lower compared to an HDP process. The different ion energies also affect the film composition and characteristics between HDP and PECVD or PEALD processes, including sputter processes as described herein. Because of these various differences, particularly the difference in pressure and plasma generation and control techniques, process conditions for HDP deposition cannot be extrapolated to capacitively-coupled plasma processes such as those described herein.

As noted above, sputtering may have two benefits. First, it re-deposits sputtered film into the bottom of the feature. Second, it changes the shape of the gap between the oxide film to have a tapered shape, improving the ability of reactants to be distributed within features and deposit at the bottom of features. In some embodiments, sputtering may also help densify the oxide film by sputtering low-density portions of the film (e.g., sputtering a seam that may be forming from prior deposition processes). The lower density film may be more easily sputtered, allowing the oxide material to re-deposit and form a higher-density film (or for a separate deposition process to deposit a higher-density film).

The amount of sputtering may be controlled by at least three parameters: pressure of the process chamber, gas flow, and RF settings. Generally, lower pressure and higher LF power increase sputtering. Furthermore, the gas flow may be controlled to introduce more inert gas, particularly more argon, to increase sputtering. In some embodiments, as discussed further herein, the process gas used for sputtering may also comprise oxygen-containing species, and a higher ratio of Ar:O may increase sputtering.

In operation 208 oxide material is deposited. Operation 208 may be performed under the same process conditions as operation 204 or different process conditions. In some embodiments, the oxide material deposited in operations 204 and 208 is the same oxide material, e.g., silicon oxide. In some embodiments oxide material may be deposited in operation 208 using a CVD or ALD process, including plasma-enhanced CVD or ALD processes.

In some embodiments operations 206 and 208 may be optionally repeated one or more times. Repeating operations 206 and 208 may be advantageous to gradually sputter oxide material and change the shape of the feature remaining to be filled. In some embodiments, the duration of the sputtering operation and the number of cycles for an ALD operation to deposit oxide material may be tuned in accordance with cycling operations 206 and 208. For example, a sputtering process may be performed for 1 cycle for each 10 cycles of ALD deposition (where a single cycle of ALD deposition may include each of operations (i)-(iv) as described above). In some embodiments a ratio of sputtering to ALD cycles may be defined, where the ratio may be between about 1:1 and about 50:1.

In embodiments where multiple sputtering operations are performed, the process parameters of the sputtering operation may change between operations. For example, it may be desirable to increase the amount of sputtering for later sputtering operations. In such embodiments, the parameters may be changed to increase the amount of sputtering for later operations. For example, the LF power for a second sputtering operation may be increased compared to a first sputtering operation to increase the amount of sputtering in the second sputtering operation. In some embodiments other process parameters may also be modified to increase/decrease sputtering, including those parameters discussed above.

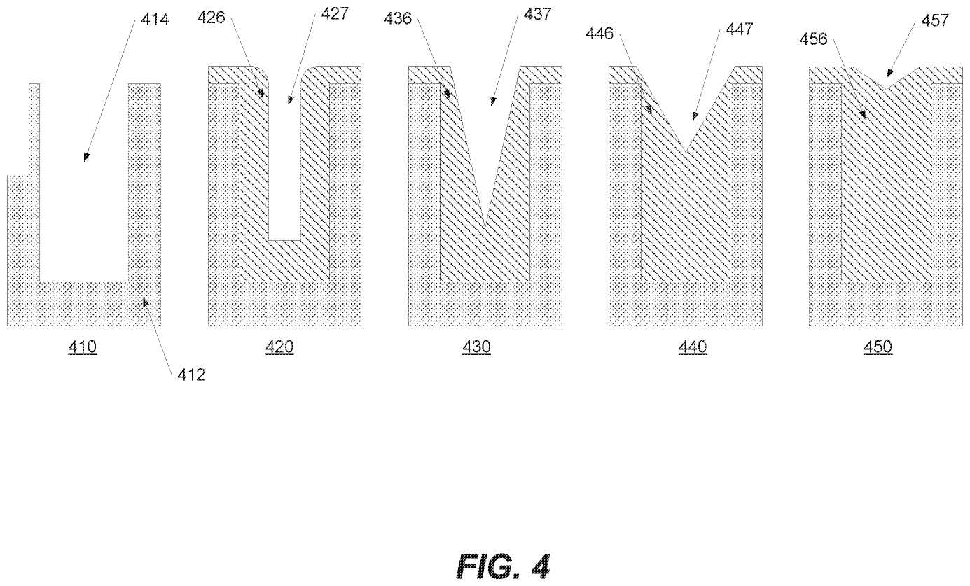

FIG. 4 presents illustrations of a process comprising multiple sputtering operations. Diagram 410 presents a substrate having a patterned layer 412 and a feature 414, similar to diagram 110 above. In diagram 420, an oxide film 426 has been conformally deposited in the feature 114, defining a gap 427 similar to diagram 120, above. In diagram 430, the oxide film 426 has been sputtered to form an oxide film 436 having a gap 437. The gap 437 tapers downward in the feature, providing more space between the oxide films at the top of the feature compared to deeper in the feature.

In diagram 440, one or more additional deposition and sputtering operations have been performed. Thus, an oxide film 446 and gap 447 are formed, where gap 447 has a wider “V” shape than gap 437, as oxide material has been sputtered from the top of the feature and deposited at the bottom of the gap. In diagram 450 further deposition and sputtering operations are performed, resulting in the feature being completely filled by oxide material 456. A gap 457 has a wider opening than both of gaps 437 and 447. The deposition and sputtering operations performed between diagrams 430 and 440 may be the same deposition and sputtering operations performed between diagrams 440 and 450, or different operations. For example, the process conditions may be changed to increase the amount of sputtering for subsequent sputtering operations. Techniques for tuning process conditions to control an amount of sputtering are discussed elsewhere herein.

The process flow discussed above describes deposition and sputtering as separate processes that may be performed in a process chamber. For example, 100 cycles of ALD may be performed to deposit oxide material, followed by 30 seconds of sputtering, and then another 100 cycles of ALD may be performed to deposit additional oxide material. However, in some embodiments the deposition and sputter operations may be integrated, such that one part of an ALD cycle comprises a sputter process.

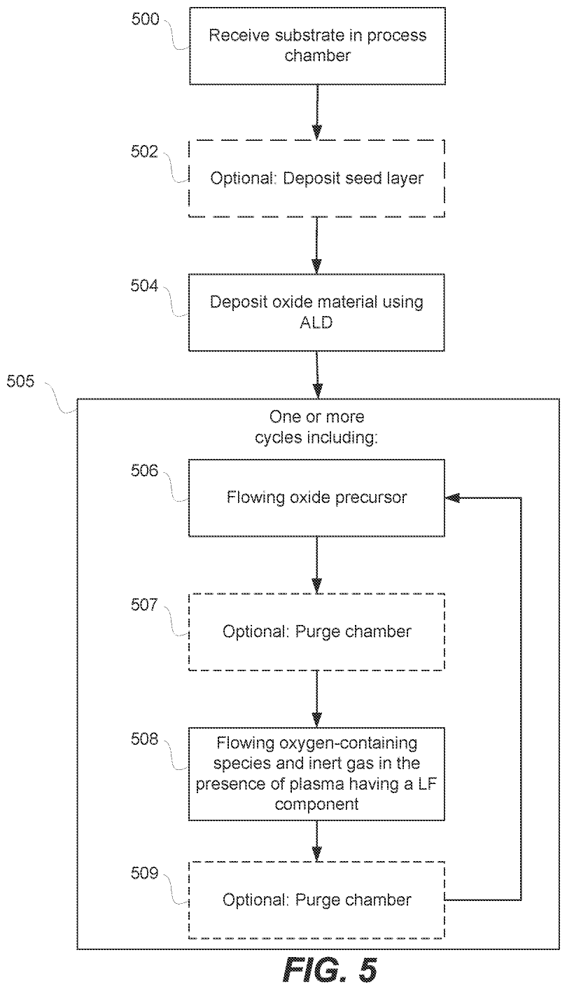

FIG. 5 presents a process flow for depositing oxide material where sputtering occurs as part of an ALD process. Starting in operation 500, a substrate is received in a process chamber. In operation 502 a seed layer is optionally deposited, and in operation 504 oxide material may be deposited by an ALD process. Operations 500-504 may be performed in a similar manner as described above in relation to operations 200-204.

Operation 505 is a PEALD process to deposit and sputter oxide material comprising 4 operations. In operation 506, oxide precursor is flowed into the chamber, which adsorbs onto the substrate surface. In an optional process 507 the oxide precursor is purged from the process chamber by, e.g., an inert gas, so that only the adsorbed species remain.

In operation 508 an oxygen-containing species and an inert gas are flowed into the process chamber in the presence of a plasma having an LF component. The oxygen-containing species react with the adsorbed oxide precursor to form oxide material. Simultaneously with this reaction, the LF component of the plasma causes the inert gas to dissociate into ions that bombard the substrate when a RF bias is applied to the substrate. The ions may thus sputter the oxide material. As the etch rate is typically higher along a horizontal surface than a sidewall, the top of the features may experience greater sputtering than the sidewalls. This may result in the tapered shape illustrated in FIG. 4.

In an optional process 509 the oxygen-containing species is purged from the process chamber by, e.g., an inert gas, so that only the adsorbed species remain. It should be understood that in various embodiments an inert gas is also flowed with the oxide precursor, however the presence of a LF component causes the bombardment of the substrate, such that the absence of a LF component does not cause sputtering of the substrate. Operations 506-509 may then be repeated one or more times to continuously deposit/sputter an oxide film.

As noted above, in some embodiments the amount of sputtering may be changed as the oxide film grows. In such embodiments, the pressure, gas flow ratios, LF power, or any combination thereof may be changed during operation 505 to increase and/or decrease the amount of sputtering.

One advantage of the process of FIG. 5 is that the sputter operation is integrated with the ALD process, improving the efficiency of the film deposition compared to separate sputter and ALD operations. As increasing LF power increases sputtering of the substrate, the LF power, amongst other parameters, may be tuned to sufficiently sputter the film during the oxidation of the adsorbed oxide precursor to form oxide material. In particular, the film may be sputtered such that the oxide film may grow preferentially near the bottom of features despite the conformal mechanism of an ALD process. In some embodiments, an oxide film may grow as illustrated in FIG. 4, except each of diagrams 430-450 may result from one or more cycles of operation 505, rather than separate sputter and deposition operations as described in FIG. 2.

In embodiments where a combination of any of ALD, PEALD, CVD, and PECVD are used to deposit oxide material, the same reactants and precursors may be used during both techniques. In some embodiments, different precursors may be selected depending on the technique. For example, in some embodiments, ALD may be performed using a halosilane, followed by PECVD using silane as the silicon-containing precursor. In some embodiments, a plasma is ignited during one or more of the techniques used to deposit the oxide material.

### Process Window

This section describes various process parameters that may be employed to produce oxide films. The process parameters are provided for a plasma enhanced atomic layer deposition process that includes a sputtering operation and takes place in a process chamber such as one described below.

In various embodiments, the total pressure in the process chamber is between about 10 mTorr and about 8 Torr. In some embodiments, the pressure in the process chamber is between about 500 mTorr and about 1 Torr, or between about 2 Torr and about 6 Torr, or between about 1 Torr and 20 Torr. As noted above, decreasing pressure typically increases the amount of sputtering. In some embodiments, the pressure may be increased or decreased during or between operations as described herein to decrease or increase the amount of sputtering, respectively.

In some embodiments the oxide material may be silicon oxide or a metal oxide, e.g., GeO₂, HfO₂, AlO₃, etc., or any combinations thereof. For depositing silicon oxide or other silicon-containing films described herein, one or more silicon-containing precursors may be used. Silicon-containing precursors suitable for use in accordance with disclosed embodiments include polysilanes (H₃Si—(SiH₂)ₙ—SiH₃), where n≥0. Examples of silanes are silane (SiH₄), disilane (SizH₆), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes, and fluorosilanes. Although halosilanes, particularly fluorosilanes, may form reactive halide species that can etch silicon materials when a plasma is struck, a halosilane may not be introduced to the chamber when a plasma is struck in some embodiments, so formation of a reactive halide species from a halosilane may be mitigated. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-, di-, tri- and tetra-aminosilane(H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino)silane(SiH₂ (NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃. di-isopropylaminosilane(DIPAS), di-sec-butylaminosilane(DSBAS), SiH₂[N(CH₂CH₃)₂]₂ (BDEAS) and the like. A further example of an aminosilane is trisilylamine (N(SiH₃)).

In some implementations silicon-containing precursors may include siloxanes or amino-group-containing siloxanes. In some embodiments, siloxanes used herein may have a formula of X(R¹)ₐSi—O—Si(R²)_{b}Y, where a and b are integers from 0 to 2, and X and Y independently can be H or NR³R⁴, where each of R¹, R², R³ and R⁴ is hydrogen, unbranched alkyl, branched alkyl, saturated heterocyclic, unsaturated heterocyclic groups, or combinations thereof. In some embodiments, when at least one X or Y is NR³R⁴, R³ and R⁴, taken together with the atom to which each are attached, form a saturated heterocyclic compound. In some embodiments, the silicon-containing precursors are pentamethylated amino group containing siloxanes or dimethylated amino group containing siloxanes. Examples of amino group containing siloxanes include: 1-diethylamino 1,1,3,3,3,-pentamethyl disiloxane, 1-diisopropylamino-1,1,3,3,3,-pentamethyl disiloxane, 1 dipropylamino-1,1,3,3,3,-pentamethyl disiloxane, 1-di-n-butylamino-1,1,3,3,3,-pentamethyl disiloxane, 1-di-sec-butylamino-1,1,3,3,3,-pentamethyl disiloxane, 1-N-methylethylamino 1,1,3,3,3,-pentamethyl disiloxane, 1-N-methylpropylamino-1,1,3,3,3,-pentamethyl disiloxane, 1 N-methylbutylamino-1,1,3,3,3,-pentamethyl disiloxane, 1-t-butylamino-1,1,3,3,3,-pentamethyl disiloxane, 1-piperidino-1,1,3,3,3,-pentamethyl disiloxane, 1-dimethylamino-1,1-dimethyl disiloxane, 1-diethylamino-1,1-dimethyl disiloxane, 1-diisopropylamino-1,1-dimethyl disiloxane, 1-dipropylamino-1,1-dimethyl disiloxane, 1-di-n-butylamino-1,1-dimethyl disiloxane, 1-di-see butylamino-1,1-dimethyl disiloxane, 1-N-methylethylamino-1,1-dimethyl disiloxane, 1-N methylpropylamino-1,1-dimethyl disiloxane 1-N-methylbutylamino-1,1-dimethyl disiloxane, 1-piperidino-1,1-dimethyl disiloxane, 1-t-butylamino-1,1-dimethyl disiloxane, 1-dimethylamino-disiloxane, 1-diethylamino-disiloxane, 1-diisopropylamino-disiloxane, 1-dipropylamino-disiloxane, 1-di-n-butylamino-disiloxane, 1-di-sec-butylamino-disiloxane, 1-N methylethylamino-disiloxane, 1-N-methylpropylamino-disiloxane, 1-N-methylbutylamino-disiloxane, 1-piperidino-disiloxane, 1-t-butylamino disiloxane, and 1-dimethylamino-1,1,5,5,5,-pentamethyl disiloxane.

Examples of oxygen-containing reactants include, but are not limited to, oxygen (O₂), ozone (O₃), nitrous oxide (N₂O), nitric oxide (NO), nitrogen dioxide (NO₂), dinitrogen trioxide (N₂O₃), dinitrogen tetroxide (N₂O₄), dinitrogen pentoxide (N₂O₅), carbon monoxide (CO), carbon dioxide (CO₂), sulfur oxide (SO), sulfur dioxide (SO₂), oxygen-containing hydrocarbons (CₓH_{y}O_{z}), water (H₂O), formaldehyde (CH₂O), carbonyl sulfide (COS), mixtures thereof, etc.

In various embodiments, the substrate is exposed to an oxidizing chemistry and an inert gas simultaneously while the plasma is ignited. For example, in one embodiment, a mixture of oxygen and argon is introduced to the substrate while the plasma is ignited. In some embodiments, the inert gas acts as a carrier gas to deliver the process gases to the substrate and is diverted upstream of the chamber. For deposition by ALD or PEALD, the silicon-containing precursor and the reactant are introduced sequentially in pulses, which may be separated by purging operations.

In some embodiments the inert gas comprises helium, nitrogen, argon, xenon, or any combination thereof. In some embodiments, the inert gas used for sputtering operations comprises argon.

During sputtering operations the inert gas flow may be between about 1 slm and about 25 slm. As noted above, inert gas flow may be increased to increase the amount of sputtering of the substrate. In some embodiments, the duration of a sputtering operation may be at least 200 milliseconds (ms), or between about 200 ms and about 250 seconds. In embodiments where sputtering operations and ALD operations are cycled, the duration of sputtering operations between ALD operations (which may include one or more ALD cycles) is at least about 200 ms seconds, or between 200 ms and 10 seconds.

In some embodiments oxidation and sputtering are occurring during the same operation (e.g., operation 508, above). Oxygen-containing gas volumetric flow rates depend on the particular process chamber, substrate, and other process conditions. In particular, where the ALD process and sputtering process are integrated, the ratio between the oxygen-containing species and the inert gas affects the degree of sputtering. A higher ratio of, e.g., Ar:O increases the amount of sputtering. In some embodiments the ratio of Ar:O may be between 1:2 and 6:1. Examples of volumetric flow rates that may be used for a single 300 mm substrate are between about 100 sccm and about 5000 sccm of oxygen and between about 3000 sccm and about 25 slm of argon. Other oxygen-containing species and inert gases may be used with suitable modification as understood by those with skill in the art. Unless otherwise specified, the flow rates disclosed herein are for a single station tool configured for 300 mm wafers. Flow rates generally scale linearly with the number of stations and substrate area.

In some embodiments, low frequency (LF) RF power refers to an RF power having a frequency between about 100 kHz and about 2 MHz. In some embodiments, LF RF power has an RF power with a frequency of about 400 kHz. High frequency RF power refers to an RF power having a frequency between about 2 MHz and about 60 MHz. In some embodiments, HF RF power has an RF power with a frequency of about 13.56 MHz or about 27 MHz.

In some embodiments, the HF power per substrate range is between about 500 W and about 6.5 kW per 300 mm substrate. In some embodiments, the HF power per substrate ranges between about 4 kW and about 5 kW. In some embodiments, the LF power is between about 500 W and 5 kW. In some embodiments, the LF power per substrate is between about 1 kW and 5 kW. In some embodiments, the LF power per substrate is about 4 kW. In many embodiments, the minimum power of the HF RF component and the minimum power of the LF RF component are sufficient to maintain a plasma. All powers provided herein are per 300 mm substrate. RF power as described herein generally scales linearly with number of stations and area of wafers.

In some embodiments a layer of oxide material is deposited prior to any sputtering operations. In various embodiments this layer may have a thickness of about 65 Å, or between about 5% and about 35% of the width of the feature.

### Apparatus

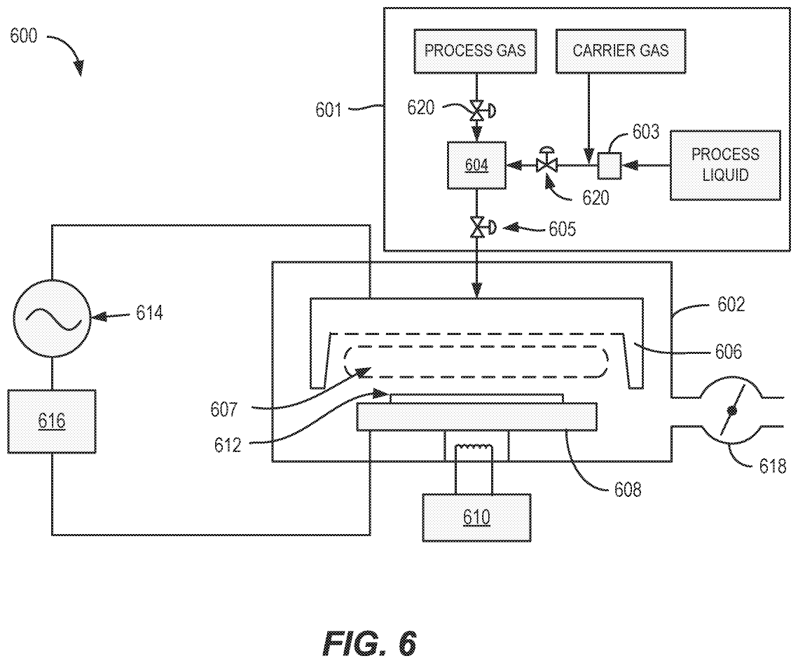

FIG. 6 schematically shows an embodiment of a process station 600 that may be used to deposit material using atomic layer deposition (ALD) and/or chemical vapor deposition (CVD), either of which may be plasma enhanced. For simplicity, the process station 600 is depicted as a standalone process station having a process chamber body 602 for maintaining a low-pressure environment. However, it will be appreciated that a plurality of process stations 600 may be included in a common process tool environment. Further, it will be appreciated that, in some embodiments, one or more hardware parameters of process station 600, including those discussed in detail below, may be adjusted programmatically by one or more computer controllers.

Process station 600 fluidly communicates with reactant delivery system 601 for delivering process gases to a distribution showerhead 606. Reactant delivery system 601 includes a mixing vessel 604 for blending and/or conditioning process gases for delivery to showerhead 606. One or more mixing vessel inlet valves 620 may control introduction of process gases to mixing vessel 604. Similarly, a showerhead inlet valve 605 may control introduction of process gasses to the showerhead 606.

Some reactants, like BTBAS, DIPAS, and DSBAS, may be stored in liquid form prior to vaporization at and subsequent delivery to the process station. For example, the embodiment of FIG. 6 includes a vaporization point 603 for vaporizing liquid reactant to be supplied to mixing vessel 604. In some embodiments, vaporization point 603 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 603 may be heat traced. In some examples, mixing vessel 604 may also be heat traced. In one non-limiting example, piping downstream of vaporization point 603 has an increasing temperature profile extending from approximately 100° C. to approximately 150° C. at mixing vessel 604.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 603. In one scenario, a liquid injector may be mounted directly to mixing vessel 604. In another scenario, a liquid injector may be mounted directly to showerhead 606.

In some embodiments, a liquid flow controller upstream of vaporization point 603 may be provided for controlling a mass flow of liquid for vaporization and delivery to process station 600. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 606 distributes process gases toward substrate 612. In the embodiment shown in FIG. 6, substrate 612 is located beneath showerhead 606, and is shown resting on a pedestal 608. It will be appreciated that showerhead 606 may have any suitable shape, and may have any suitable number and arrangement of ports for distributing processes gases to substrate 612.

In some embodiments, a microvolume 607 is located beneath showerhead 606. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 608 may be raised or lowered to expose substrate 612 to microvolume 607 and/or to vary a volume of microvolume 607. For example, in a substrate transfer phase, pedestal 608 may be lowered to allow substrate 612 to be loaded onto pedestal 608. During a deposition process phase, pedestal 608 may be raised to position substrate 612 within microvolume 607. In some embodiments, microvolume 607 may completely enclose substrate 612 as well as a portion of pedestal 608 to create a region of high flow impedance during a deposition process.

Optionally, pedestal 608 may be lowered and/or raised during portions the deposition process to modulate process pressure, reactant concentration, etc., within microvolume 607. In one scenario where process chamber body 602 remains at a base pressure during the deposition process, lowering pedestal 608 may allow microvolume 607 to be evacuated. Example ratios of microvolume to process chamber volume include, but are not limited to, volume ratios between 1:100 and 1:10. It will be appreciated that, in some embodiments, pedestal height may be adjusted programmatically by a suitable computer controller.

In another scenario, adjusting a height of pedestal 608 may allow a plasma density to be varied during plasma activation and/or treatment cycles included in the deposition process. At the conclusion of the deposition process phase, pedestal 608 may be lowered during another substrate transfer phase to allow removal of substrate 612 from pedestal 608.

While the example microvolume variations described herein refer to a height-adjustable pedestal, it will be appreciated that, in some embodiments, a position of showerhead 606 may be adjusted relative to pedestal 608 to vary a volume of microvolume 607. Further, it will be appreciated that a vertical position of pedestal 608 and/or showerhead 606 may be varied by any suitable mechanism within the scope of the present disclosure. In some embodiments, pedestal 608 may include a rotational axis for rotating an orientation of substrate 612. It will be appreciated that, in some embodiments, one or more of these example adjustments may be performed programmatically by one or more suitable computer controllers.

Returning to the embodiment shown in FIG. 6, showerhead 606 and pedestal 608 electrically communicate with RF power supply 614 and matching network 616 for powering a plasma. In some embodiments, the plasma energy may be controlled by controlling one or more of a process station pressure, a gas concentration, an RF source power, an RF source frequency, and a plasma power pulse timing. For example, RF power supply 614 and matching network 616 may be operated at any suitable power to form a plasma having a desired composition of radical species. Examples of suitable powers are included above. Likewise, RF power supply 614 may provide RF power of any suitable frequency. In some embodiments, RF power supply 614 may be configured to control high- and low-frequency RF power sources independently of one another. Example low-frequency RF frequencies may include, but are not limited to, frequencies between 50 kHz and 600 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 608 may be temperature controlled via heater 610. Further, in some embodiments, pressure control for deposition process station 600 may be provided by butterfly valve 618. As shown in the embodiment of FIG. 6, butterfly valve 618 throttles a vacuum provided by a downstream vacuum pump (not shown). However, in some embodiments, pressure control of process station 600 may also be adjusted by varying a flow rate of one or more gases introduced to process station 600.

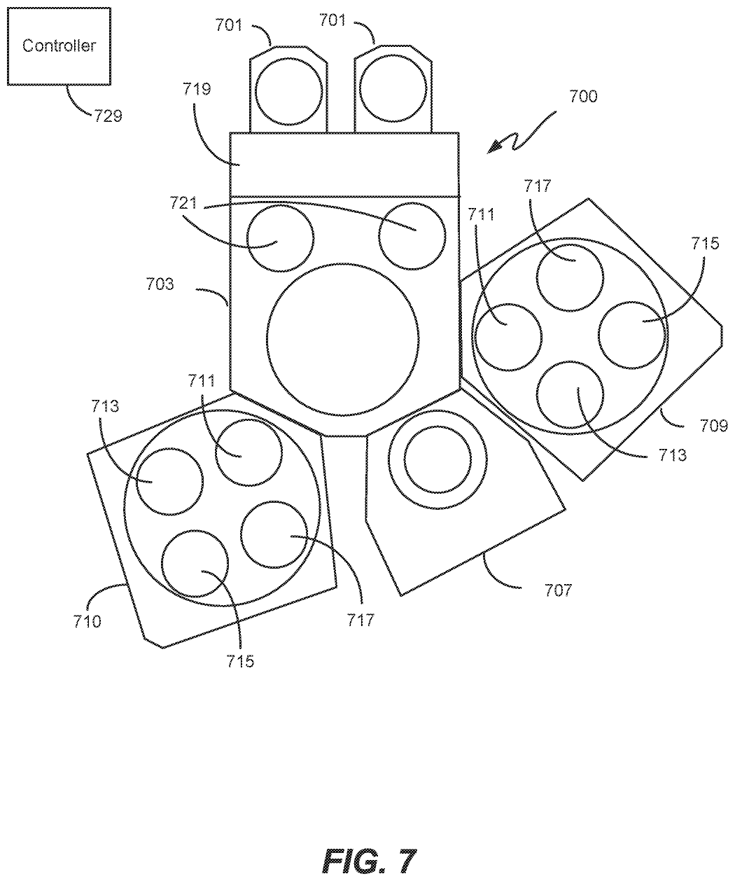

FIG. 7 is a block diagram of a processing system suitable for conducting thin film deposition processes in accordance with certain embodiments. The system 700 includes a transfer module 703. The transfer module 703 provides a clean, pressurized environment to minimize risk of contamination of substrates being processed as they are moved between various reactor modules. Mounted on the transfer module 703 are two multi-station reactors 709 and 710, each capable of performing atomic layer deposition (ALD) and/or chemical vapor deposition (CVD) according to certain embodiments. Reactors 709 and 710 may include multiple stations 711, 713, 715, and 717 that may sequentially or non-sequentially perform operations in accordance with disclosed embodiments. The stations may include a heated pedestal or substrate support, one or more gas inlets or showerhead or dispersion plate.

Also mounted on the transfer module 703 may be one or more single or multi-station modules 707 capable of performing plasma or chemical (non-plasma) pre-cleans, or any other processes described in relation to the disclosed methods. The module 707 may in some cases be used for various treatments to, for example, prepare a substrate for a deposition process. The module 707 may also be designed/configured to perform various other processes such as etching or polishing. The system 700 also includes one or more wafer source modules 701, where wafers are stored before and after processing. An atmospheric robot (not shown) in the atmospheric transfer chamber 719 may first remove wafers from the source modules 701 to loadlocks 721. A wafer transfer device (generally a robot arm unit) in the transfer module 703 moves the wafers from loadlocks 721 to and among the modules mounted on the transfer module 703.

In various embodiments, a system controller 729 is employed to control process conditions during deposition. The controller 729 will typically include one or more memory devices and one or more processors. A processor may include a CPU or computer, analog and/or digital input/output connections, stepper motor controller boards, etc.

The controller 729 may control all of the activities of the deposition apparatus. The system controller 729 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 729 may be employed in some embodiments.

Typically there will be a user interface associated with the controller 729. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 729. The signals for controlling the process are output on the analog and digital output connections of the deposition apparatus 700.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller 729 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 729, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

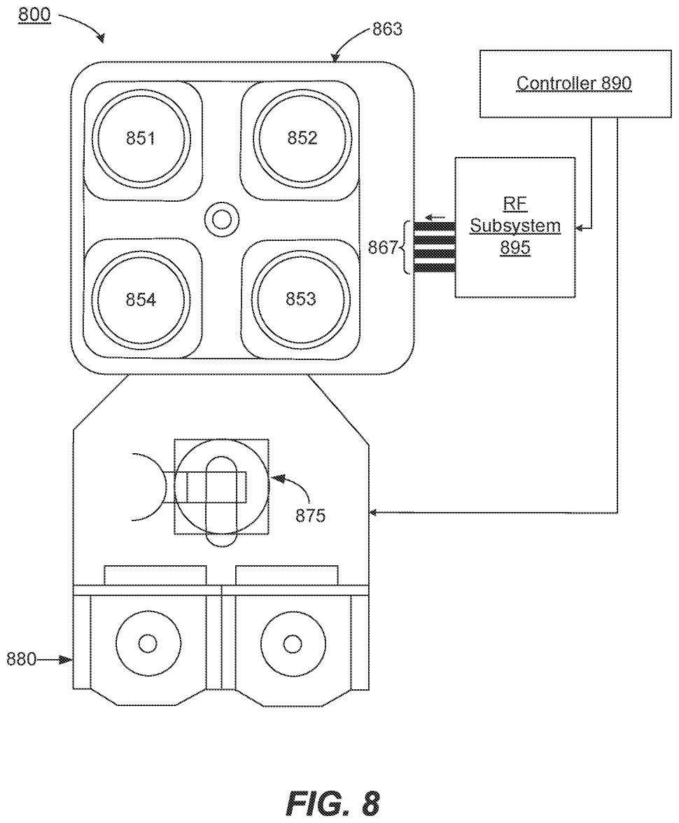

It may be appreciated that a plurality of process stations may be included in a multi-station processing tool environment, such as shown in FIG. 8, which depicts a schematic view of an embodiment of a multi-station processing tool. Processing apparatus 800 employs an integrated circuit fabrication chamber 863 that includes multiple fabrication process stations, each of which may be used to perform processing operations on a substrate held in a wafer holder, such as a pedestal, at a particular process station. In the embodiment of FIG. 8, the integrated circuit fabrication chamber 863 is shown having four process stations 851, 852, 853, and 854. Other similar multi-station processing apparatuses may have more or fewer process stations depending on the implementation and, for example, a desired level of parallel wafer processing, size/space constraints, cost constraints, etc. Also shown in FIG. 8 is substrate handler robot 875, which may operate under the control of system controller 890, configured to move substrates from a wafer cassette (not shown in FIG. 8) from loading port 880 and into integrated circuit fabrication chamber 863, and onto one of process stations 851, 852, 853, and 854.

FIG. 8 also depicts an embodiment of a system controller 890 employed to control process conditions and hardware states of processing apparatus 800. System controller 890 may include one or more memory devices, one or more mass storage devices, and one or more processors, as described herein.

RF subsystem 895 may generate and convey RF power to integrated circuit fabrication chamber 863 via radio frequency input ports 867. In particular embodiments, integrated circuit fabrication chamber 863 may comprise input ports in addition to radio frequency input ports 867 (additional input ports not shown in FIG. 8). Accordingly, integrated circuit fabrication chamber 863 may utilize 8 RF input ports. In particular embodiments, process stations 851-854 of integrated circuit fabrication chamber 165 may each utilize first and second input ports in which a first input port may convey a signal having a first frequency and in which a second input port may convey a signal having a second frequency. Use of dual frequencies may bring about enhanced plasma characteristics.

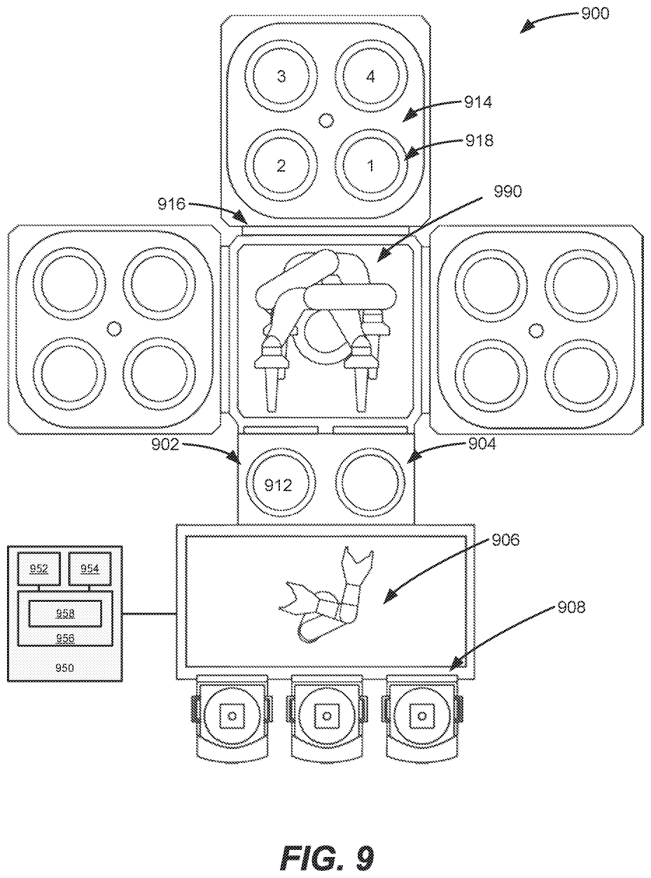

As described above, one or more process stations may be included in a multi-station processing tool. FIG. 9 shows a schematic view of an embodiment of a multi-station processing tool 900 with an inbound load lock 902 and an outbound load lock 904, either or both of which may comprise a remote plasma source. A robot 906, at atmospheric pressure, is configured to move substrates or wafers from a cassette loaded through a pod 908 into inbound load lock 902 via an atmospheric port 910. A substrate is placed by the robot 906 on a pedestal 912 in the inbound load lock 902, the atmospheric port 910 is closed, and the load lock is pumped down. Where the inbound load lock 902 comprises a remote plasma source, the substrate may be exposed to a remote plasma treatment in the load lock prior to being introduced into a processing chamber 914. Further, the substrate also may be heated in the inbound load lock 902 as well, for example, to remove moisture and adsorbed gases. Next, a chamber transport port 916 to processing chamber 914 is opened, and another robot (not shown) places the substrate into the reactor on a pedestal of a first station shown in the reactor for processing. While the embodiment depicted in FIG. 9 includes load locks, it will be appreciated that, in some embodiments, direct entry of a substrate into a process station may be provided. In various embodiments, the soak gas is introduced to the station when the substrate is placed by the robot 906 on the pedestal 912.

The depicted processing chamber 914 comprises four process stations, numbered from 1 to 4 in the embodiment shown in FIG. 9. Each station has a heated pedestal (shown at 918 for station 1), and gas line inlets. It will be appreciated that in some embodiments, each process station may have different or multiple purposes. For example, in some embodiments, a process station may be switchable between an ALD and PEALD process mode. Additionally or alternatively, in some embodiments, processing chamber 914 may include one or more matched pairs of ALD and plasma-enhanced ALD process stations. While the depicted processing chamber 914 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 9 depicts an embodiment of a wafer handling system 990 for transferring substrates within processing chamber 914. In some embodiments, wafer handling system 990 may transfer substrates between various process stations and/or between a process station and a load lock. It will be appreciated that any suitable wafer handling system may be employed. Non-limiting examples include wafer carousels and wafer handling robots. FIG. 9 also depicts an embodiment of a system controller 950 employed to control process conditions and hardware states of process tool 900. System controller 950 may include one or more memory devices 956, one or more mass storage devices 954, and one or more processors 952. Processor 952 may include a CPU or computer, analog and/or digital input/output connections, stepper motor controller boards, etc. In some embodiments, system controller 950 includes machine-readable instructions for performing operations such as those described herein.

In some embodiments, system controller 950 controls the activities of process tool 900. System controller 950 executes system control software 958 stored in mass storage device 954, loaded into memory device 956, and executed on processor 952. Alternatively, the control logic may be hard coded in the system controller 950. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 958 may include instructions for controlling the timing, mixture of gases, amount of gas flow, chamber and/or station pressure, chamber and/or station temperature, substrate temperature, target power levels, RF power levels, substrate pedestal, chuck and/or susceptor position, and other parameters of a particular process performed by process tool 900. System control software 958 may be configured in any suitable way. For example, various process tool component subroutines or control objects may be written to control operation of the process tool components used to carry out various process tool processes. System control software 958 may be coded in any suitable computer readable programming language.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of depositing an oxide material, comprising:
depositing a conformal seed layer of oxide material into at least one patterned feature of a semiconductor substrate provided within a process chamber; and
one or more cycles comprising:
sputtering the oxide material using an inert gas in the presence of a plasma generated by a dual radio frequency (RF) plasma source comprising a high frequency (HF) component and a low frequency (LF) component; and
depositing the oxide material into the at least one patterned feature by an atomic layer deposition (ALD) process.

2. The method of claim 1, wherein each cycle of the one or more cycles comprises:
(a) sputtering the oxide material; and
(b) conformally depositing the oxide material by multiple cycles of the ALD process.

3. The method of claim 1, wherein each cycle of the one or more cycles further comprises:
(a) flowing oxide precursor into the process chamber;
(b) flowing purge gas into the process chamber;
(c) flowing an oxygen-containing species and an inert gas into the process chamber; and
(d) flowing purge gas into the process chamber.

4. The method of claim 3, wherein the oxide precursor is an amino group containing siloxane.

5. The method of claim 3, wherein the oxide precursor is a disiloxane having a formula X(R¹)ₐSi—O—Si(R²)_{b}Y, wherein a and b are integers from 0 to 2, wherein X and Y independently can be H or NR³R⁴, and wherein each of R¹, R², R³ and R⁴ is hydrogen, unbranched alkyl, branched alkyl, saturated heterocyclic, unsaturated heterocyclic groups, or combinations thereof.

6. The method of claim 5, wherein X, Y, or both is NR³R⁴, and wherein R³, R⁴, and the atom to which they are attached form a saturated heterocyclic compound.

7. The method of claim 3, wherein the plasma source has a non-zero LF component power during (c).

8. The method of claim 3, wherein a volumetric flow ratio between the inert gas and the oxygen-containing species is at least about 1:1.

9. The method of claim 3, wherein a volumetric flow ratio between the inert gas and the oxygen-containing species is between about 1:1 and 6:1.

10. The method of claim 3, further comprising a first cycle of the one or more cycles and a second cycle of the one or more cycles, wherein the LF component power, process chamber pressure, ratio between the inert gas and the oxygen-containing species, or any combination thereof is different between the second cycle and the first cycle.

11. The method of claim 10, wherein the process chamber pressure is lower during the second cycle than during the first cycle.

12. The method of claim 10, wherein a ratio between the inert gas and the oxygen-containing species is higher during the second cycle than during the first cycle.

13. The method of claim 10, wherein the LF component power is higher during the second cycle than during the first cycle.

14. The method of claim 1, wherein the oxide material is at least about 6.5 nm thick prior to sputtering.

15. The method of claim 1, further comprising flowing an oxygen-containing species into the process chamber during sputtering.

16. The method of claim 1, wherein the one or more cycles comprise at least about 100 cycles.

17. The method of claim 1, wherein the LF component power during sputtering is at least about 500 W.

18. The method of claim 1, wherein the LF component power during sputtering is between about 500 W and 5 kW.

19. The method of claim 1, wherein the HF component power is between about 500 W and about 6.5 kW.

20. The method of claim 1, wherein a pressure of the process chamber is between about 10 mTorr and about 20 Torr.

21. The method of claim 1, wherein the ALD process is performed in the presence of a plasma.

22. The method of claim 21, wherein the LF component power during the ALD process is OW and the LF component power is at least about 1000 kW during sputtering.

23. The method of claim 1, wherein the inert gas comprises argon.

24. The method of claim 1, wherein the oxide material does not have a seam at least about 50 nm below a top of the at least one patterned feature.

25. The method of claim 1, wherein a patterned feature of the at least one patterned feature has an aspect ratio of between about 1:1 and about 10:1.

26. A method of depositing an oxide material, comprising:
depositing a conformal seed layer of oxide material into at least one patterned feature of a layer of a semiconductor substrate provided within a process chamber;
depositing oxide material by a plasma enhanced atomic layer deposition (PEALD) process, wherein the process comprises:
(a) igniting a plasma generated by a dual radio frequency (RF) plasma source comprising a high frequency (HF) component and a low frequency (LF) component,
(b) flowing oxide precursor into the process chamber,
(c) flowing purge gas into the process chamber,
(d) flowing an oxygen-containing species and an inert gas into the process chamber,
(e) flowing purge gas into the process chamber, and
wherein the LF component power is increased during (d).
